(19) United States
(12) Patent Application Publication
(10) Pub. No.: US 2021/0350948 A1
(43) Pub. Date: Nov. 11, 2021

(54) FULL-AREA ALUMINUM BACK SURFACE FIELD BACK-SIDE SILVER PASTE AND PREPARATION METHOD AND APPLICATION THEREOF

(71) Applicant: NANTONG T-SUN NEW ENERGY CO., LTD., Jiangsu (CN)

(72) Inventor: Peng ZHU, Jiangsu (CN)

(73) Assignee: NANTONG T-SUN NEW ENERGY CO., LTD., Jiangsu (CN)

(21) Appl. No.: 17/277,307

(22) PCT Filed: Aug. 2, 2018
(86) PCT No.: PCT/CN2018/098230

§ 371 Date: Mar. 18, 2021

(30) Foreign Application Priority Data
Jul. 6, 2018 (CN) 201810739434.1

(51) Int. Cl. H01B 1/22; C09D 11/52; C09D 11/037

(52) U.S. Cl. CPC H01B 1/22; H01L 31/022441; C09D 11/037; C09D 11/52

(57) ABSTRACT

The present invention discloses a full-area aluminum back surface field back-side silver paste and a preparation method and application thereof. The full-area aluminum back surface field back-side silver paste comprises: 10 to 80 parts by weight of silver powder with purity higher than 99.99% under special requirements; 0.5 to 5 parts by weight of homemade lead-free main glass powder; 0 to 3 parts by weight of low-melting-point auxiliary glass powder; 1 to 50 parts by weight of low-melting-point metal powder under special requirements; 15 to 50 parts by weight of organic binder; and 0.01 to 1 part by weight of organic additives.

### BACKGROUND

### Technical Field

The present invention belongs to the technical field of solar cells, and particularly relates to a full-area aluminum back surface field back-side silver paste and a preparation method and application thereof.

### Description of Related Art

Conventional back-side silver paste is directly printed on the back of a silicon wafer, back-side aluminum is then aligned and printed, and electrodes form ohmic contact with the back-side aluminum and the wafer by sintering. Such cells mainly have the following defects: since the back electrodes are directly printed on the wafer to form ohmic contact, it is very easy for the silver electrodes to form metal defects in the wafer, and as a result, the electrodes become severe electric leakage areas, decreasing the photoelectric conversion efficiency of the solar cell (0.1% to 0.2%); because the edges of the back electrodes need to be covered by an aluminum back surface field, the back electrode width is increased, and the cost of the back electrode paste is increased.

Low-melting-point metal powder introduced into a back electrode silver paste by the present invention has very high sintering flow activity, and plays a role of silver-aluminum barrier agent in the back electrode silver paste system to prevent interpenetration between silver and aluminum and contact between silver and a silicon wafer. The matching of low-melting-point metal powders with different grain sizes can greatly decrease contact resistance. The addition of some low-melting-point metal powder can also reduce the usage of silver powder in the paste, thereby reducing cost. Moreover, the silver paste is directly printed on back-side aluminum electrodes, preventing the severe electric leakage problem caused by metal defects as a result of the direct contact between silver and a silicon wafer, and thereby the photoelectric conversion efficiency of crystalline silicon cells can be increased. Moreover, back electrode width and printed pattern can be adjusted optionally, thereby reducing the cost of the back electrode paste.

### SUMMARY

Objective of the invention: In order to solve the defects of the prior art, the present invention provides a full-area aluminum back surface field back-side silver paste and a preparation method and application thereof.

Technical solution: A full-area aluminum back surface field back-side silver paste comprises: 10 to 80 parts by weight of silver powder with purity higher than 99.99% under special requirements; 0.5 to 5 parts by weight of homemade lead-free main glass powder; 0 to 3 parts by weight of low-melting-point auxiliary glass powder; 1 to 50 parts by weight of low-melting-point metal powder under special requirements; 15 to 50 parts by weight of organic binder; and 0.01 to 1 part by weight of organic additives.

Preferably, the silver powder under special requirements is spherical silver powder, hollow spherical silver powder, flaky silver powder or superfine silver powder; the grain size D50 of the spherical silver powder is 1 μm to 13 μm; the grain size D50 of the hollow spherical silver powder is 3 μm to 20 μm; the grain size D50 of the flaky silver powder is 2 μm to 30 μm; the grain size D50 of the superfine silver powder is 0.1 μm to 3 μm, and the specific surface area is 1.5 m²/g to 5 m²/g.

Preferably, the grain size D50 of the spherical silver powder is about 7 μm to 8 μm; the grain size D50 of the spherical micro-nano silver powder is about 1 μm to 3 μm; the grain size D50 of the flaky silver powder is about 5 μm to 10 μm; and the grain size D50 of the superfine spherical nano silver powder is about 50 nm to 100 nm.

Preferably, the homemade lead-free main glass powder is prepared by melting several of Bi₂O₃, B₂O₃, SiO₂, Al₂O₃, CuO, ZnO, Na₂O, MnO₂, CaO, TiO₂, Cr₂O₃, SrO, BaO, NiO and TeO₂, with the grain size D50 being controlled at 0.5 μm to 5 μm and the softening point being controlled at 400° C. to 600° C.

Preferably, the low-melting-point auxiliary glass powder is prepared by melting several of PbO, Bi₂O₃, MnO₂, TeO₂, B₂O₃, SiO₂, Al₂O₃, CuO, ZnO, TiO₂, Cr₂O₃, NiO and Li₂CO₃, with the grain size D50 being controlled at 1 μm to 9 μm and the softening point being controlled at 380° C. to 500° C.

Preferably, the low-melting-point metal powder under special requirements includes one or more of powder of copper, vanadium, potassium, indium, tellurium, bismuth, tin, antimony, lead and other low-melting-point metals and their alloys, wherein the spherical metallic bismuth powder under special requirements has a melting point from 200° C. to 300° C. and a grain size from about 0.1 μm to about 8 μm; the metallic tin powder under special requirements has a melting point from 200° C. to 300° C. and a grain size from about 0.5 μm to about 10 μm; the metallic antimony powder under special requirements has a melting point from 300° C. to 400° C. and a grain size from about 0.1 μm to about 8 μm; and the metallic lead powder under special requirements has a melting point from 400° C. to 500° C. and a grain size from about 0.1 μm to about 5 μm.

Preferably, the organic binder comprises organic resin and organic solvent; the organic resin is selected from one or more of ethyl cellulose, butyl cellulose acetate, polyvinyl butyral resin, phenolic resin, methyl cellulose, polycondensated aldehyde and cellulose ether; and the organic solvent is selected from one or more of acetone, terpineol, Texanol, butyl carbitol, butyl carbitol acetate, glycerol and diethylene glycol monobutyl ether.

Preferably, the organic additives include surfactant, thixotropic agent and tensile additive; the surfactant is one or more of lecithin, phosphates, phosphate salts, Span-85, carboxylic acids and macromolecular alkyl ammonium salts; and the thixotropic agent is one or more of gaseous silica, organobentonite, modified hydrogenated castor oil, Span-85, lauryl phosphate and polyamide wax.

A preparation method for the full-area aluminum back surface field back-side silver paste comprises the following steps:

(1) low-melting-point nano metal powder is uniformly dispersed separately with dispersant for later use;

(2) preparation of organic binder: organic resin and organic additives are respectively soaked with organic solvent; more specifically, the organic resin is soaked while being heated and stirred under a temperature of about 90° C. for 1 to 3 hours, and thixotropic agent is soaked while being heated and stirred under a temperature of about 40° C. for 1 to 2 hours; the organic resin and the thixotropic agent are then mixed with other organic additives and organic solvent according to a certain proportion, giving a transparent and homogeneous organic binder;

(3) preparation of inorganic binder (main glass powder and auxiliary glass powder): after being weighed according to percentages by weight, various materials are dry-mixed in a V-type mixer, and after uniform mixing, the mixture is dried in a constant-temperature drying oven under about 200° C. for 2 to 5 hours; after being taken out, the mixture is sintered and smelted in a muffle furnace under 900° C. to 1100° C. for 1 to 2 hours, and during smelting, a high-temperature nitrogen vacuum-protected sintering technique is adopted, the application of which can overcome the technical problem on how to prepare low-melting-point, valence state-table glass powder; and after being taken out of the muffle furnace, the glass is cooled by cooling rolls, ball-milled, dried and screened, giving an inorganic binder for the full-area aluminum back surface field back-side silver paste;

(4) after silver powder, the organic binder, the inorganic binder (the main glass powder and the auxiliary glass powder), organic additives and the pre-dispersed low-melting-point nano metal powder are dispersed and mixed according to a certain proportion, the mixture is ground using a three-roll grinder, 3 to 5 times with fine rolls and 2 to 3 times with rough rolls, so that the mixture is uniformly dispersed until fineness is less than 20 μm, giving the prepared full-area aluminum back surface field back-side silver paste.

An application of the full-area aluminum back surface field back-side silver paste, in which the full-area aluminum back surface field back-side silver paste is directly printed on aluminum paste to prevent the severe electric leakage problem caused by metal defects as a result of the direct contact between silver and a silicon wafer, and thereby the photoelectric conversion efficiency of crystalline silicon cells can be increased; moreover, back electrode width and printed pattern can be adjusted optionally, thereby reducing the cost of back electrode paste and ensuring that the back electrode paste has considerable welding tensile strength and aging tensile strength; in order to reduce unit consumption, the printed pattern of the back-side silver paste may be hollowed out, strip hollowed out or dot hollowed out, with the blocking proportion being 25% to 50%; and after sintering, the thickness of the formed blocking layer is between 5 μm and 30 μm.

The specific advantages of the present invention are as follows:

1. Since the silver powders with different grain sizes and shapes are chosen to be used in cooperation in the present invention, the bulk density of a conducting film is increased, the contact area between silver particles is enlarged, the contraction force of the conducting film is decreased, and the electric conductivity of the paste is increased.

2. The low-melting-point metal powder in the present invention has very high sintering flow activity, and plays a role of silver-aluminum barrier agent in the whole paste system to prevent interpenetration between silver and aluminum and contact between silver and a silicon wafer. The matching of silver-aluminum barrier agents with different grain sizes can greatly decrease contact resistance, thereby increasing the efficiency of cells. However, excessive addition of the low-melting-point metal powder will lead to a decrease in the electric conductivity of the back-side silver paste. Moreover, the addition of some low-melting-point metal powder can also reduce the usage of silver powder, thereby reducing cost.

3. In the present invention, according to the different sensitivities of the organic resin and the organic additives to temperature, the organic resin and the organic additives are dispersed separately, which not only can save time, but also can prevent the organic additives from deteriorating under high temperature.

4. The advantages of the polyvinyl butyral resin in the present invention are as follows: thickening is fast, the leveling property of the paste can be improved, and unsatisfactory lapping property between the paste and aluminum paste, high series resistance and other problems caused by poor rheological property.

5. The full-area aluminum back surface field back-side silver paste can be directly printed on aluminum back surface field paste, ensuring that the aluminum back surface field paste has considerable welding tensile strength and aging tensile strength and preventing the severe electric leakage problem caused by metal defects as a result of the direct contact between silver and a silicon wafer, and thereby the photoelectric conversion efficiency of crystalline silicon cells can be increased. Moreover, back electrode width and printed pattern can be adjusted optionally, thereby reducing the cost of back electrode paste.

6. The addition of the two types of glass powders in the form of the main glass power and the auxiliary glass powder can better enrich the softening temperature, grain size and thermal expansion property of the inorganic binder and the glass powder content in the paste. Moreover, in the process of paste sintering, the formed back electrodes can be denser, and the welding property and electric property of the electrodes can be improved.

7. By using the organic carrier, through the matching of the different solvents, the silver paste can have layered volatility, preventing the problem of too fast volatilization or too much ash content occurring in the process of paste sintering. Keeping layered volatility can prevent the production of pores on the surface of the electrode or the remaining of too much non-conductive material on the electrode, improving aging tensile strength and the electric property of the product.

### BRIEF DESCRIPTION OF THE DRAWINGS

FIG. 1 is a schematic diagram of spherical micro-nano silver powder of the present invention;

FIG. 2 is a schematic diagram of flaky silver powder of the present invention;

FIG. 3 is a schematic diagram of micron-scale monospherical silver powder of the present invention;

FIG. 4 is a schematic diagram of micron-scale spherical silver-aluminum barrier agent of the present invention;

FIG. 5 is an SEM image of the cross section of a back electrode of the present invention;

FIG. 6 is a schematic diagram of a cell structure of the present invention, in which \textcircled{1} is full-area aluminum back surface field back-side silver, \textcircled{2} is an aluminum back surface field conductive layer, \textcircled{3} is a P-type silicon substrate, \textcircled{4} is an N-type impurity layer, \textcircled{5} is an anti-reflective film passivation layer, and \textcircled{6} is a grid-type front-side electrode; and

FIG. 7 is a schematic flowchart of a preparation method for inorganic binder of the present invention.

### DESCRIPTION OF THE EMBODIMENTS

The technical solution in embodiments of the present invention will be clearly and completely described below, so that those skilled in the art can better understand the advantages and characteristics of the present invention, and thus the protection scope of the present invention can be defined more clearly. The embodiments described in the present invention are only part of the embodiments of the present invention rather than all of them. Based on the embodiments of the present invention, all other embodiments which are achieved by those of ordinary skill in the art without doing creative work shall fall within the protection scope of the present invention.

### Embodiment

A full-area aluminum back surface field back-side silver paste comprises: 10 to 80 parts by weight of silver powder with purity higher than 99.99% under special requirements; 0.5 to 5 parts by weight of homemade lead-free main glass powder; 0 to 3 parts by weight of low-melting-point auxiliary glass powder; 1 to 50 parts by weight of low-melting-point metal powder under special requirements; 15 to 50 parts by weight of organic binder; and 0.01 to 1 part by weight of organic additives.

The silver powder under special requirements is spherical silver powder, hollow spherical silver powder, flaky silver powder or superfine silver powder; the grain size D50 of the spherical silver powder is 1 μm to 13 μm; the grain size D50 of the hollow spherical silver powder is 3 μm to 20 μm; the grain size D50 of the flaky silver powder is 2 μm to 30 μm; the grain size D50 of the superfine silver powder is 0.1 μm to 3 μm, and the specific surface area is 1.5 m²/g to 5 m²/g.

The grain size D50 of the spherical silver powder is about 7 μm to 8 μm; the grain size D50 of the spherical micro-nano silver powder is about 1 μm to 3 μm; the grain size D50 of the flaky silver powder is about 5 μm to 10 μm; and the grain size D50 of the superfine spherical nano silver powder is about 50 nm to 100 nm.

The homemade lead-free main glass powder is prepared by melting several of Bi₂O₃, B₂O₃, SiO₂, Al₂O₃, CuO, ZnO, Na₂O, MnO₂, CaO, TiO₂, Cr₂O₃, SrO, BaO, NiO and TeO₂, with the grain size D50 being controlled at 0.5 μm to 5 μm and the softening point being controlled at 400° C. to 600° C.

The low-melting-point auxiliary glass powder is prepared by melting several of PbO, Bi₂O₃, MnO₂, TeO₂, B₂O₃, SiO₂, Al₂O₃, CuO, ZnO, TiO₂, Cr₂O₃, NiO and Li₂CO₃, with the grain size D50 being controlled at 1 μm to 9 μm and the softening point being controlled at 380° C. to 500° C.

The low-melting-point metal powder under special requirements includes one or more of powder of copper, vanadium, potassium, indium, tellurium, bismuth, tin, antimony, lead and other low-melting-point metals and their alloys, wherein the spherical metallic bismuth powder under special requirements has a melting point from 200° C. to 300° C. and a grain size from about 0.1 μm to about 8 μm; the metallic tin powder under special requirements has a melting point from 200° C. to 300° C. and a grain size from about 0.5 μm to about 10 μm; the metallic antimony powder under special requirements has a melting point from 300° C. to 400° C. and a grain size from about 0.1 μm to about 8 μm; and the metallic lead powder under special requirements has a melting point from 400° C. to 500° C. and a grain size from about 0.1 μm to about 5 μm.

The organic binder comprises organic resin and organic solvent; the organic resin is selected from one or more of ethyl cellulose, butyl cellulose acetate, polyvinyl butyral resin, phenolic resin, methyl cellulose, polycondensated aldehyde and cellulose ether; and the organic solvent is selected from one or more of acetone, terpineol, Texanol, butyl carbitol, butyl carbitol acetate, glycerol and diethylene glycol monobutyl ether.

The organic additives include surfactant, thixotropic agent and tensile additive; the surfactant is one or more of lecithin, phosphates, phosphate salts, Span-85, carboxylic acids and macromolecular alkyl ammonium salts; and the thixotropic agent is one or more of gaseous silica, organobentonite, modified hydrogenated castor oil, Span-85, lauryl phosphate and polyamide wax.

A preparation method for the full-area aluminum back surface field back-side silver paste comprises the following steps:

(1) low-melting-point nano metal powder is uniformly dispersed separately with dispersant for later use;

(2) preparation of organic binder: organic resin and organic additives are respectively soaked with organic solvent; more specifically, the organic resin is soaked while being heated and stirred under a temperature of about 90° C. for 1 to 3 hours, and thixotropic agent is soaked while being heated and stirred under a temperature of about 40° C. for 1 to 2 hours; the organic resin and the thixotropic agent are then mixed with other organic additives and organic solvent according to a certain proportion, giving a transparent and homogeneous organic binder;

(3) preparation of inorganic binder (main glass powder and auxiliary glass powder): as shown in FIG. 7, after being weighed according to percentages by weight, various materials are dry-mixed in a V-type mixer, and after uniform mixing, the mixture is dried in a constant-temperature drying oven under about 200° C. for 2 to 5 hours; after being taken out, the mixture is sintered and smelted in a muffle furnace under 900° C. to 1100° C. for 1 to 2 hours, and during smelting, a high-temperature nitrogen vacuum-protected sintering technique is adopted, the application of which can overcome the technical problem on how to prepare low-melting-point, valence state-table glass powder; and after being taken out of the muffle furnace, the glass is cooled by cooling rolls, ball-milled, dried and screened, giving an inorganic binder for the full-area aluminum back surface field back-side silver paste;

(4) after silver powder, the organic binder, the inorganic binder (the main glass powder and the auxiliary glass powder), organic additives and the pre-dispersed low-melting-point nano metal powder are dispersed and mixed according to a certain proportion, the mixture is ground using a three-roll grinder, 3 to 5 times with fine rolls and 2 to 3 times with rough rolls, so that the mixture is uniformly dispersed until fineness is less than 20 μm, giving the prepared full-area aluminum back surface field back-side silver paste.

An application of the full-area aluminum back surface field back-side silver paste, in which the full-area aluminum back surface field back-side silver paste is directly printed on aluminum paste to prevent the severe electric leakage problem caused by metal defects as a result of the direct contact between silver and a silicon wafer, and thereby the photoelectric conversion efficiency of crystalline silicon cells can be increased; moreover, back electrode width and printed pattern can be adjusted optionally, thereby reducing the cost of back electrode paste and ensuring that the back electrode paste has considerable welding tensile strength and aging tensile strength; in order to reduce unit consumption, the printed pattern of the back-side silver paste may be hollowed out, strip hollowed out or dot hollowed out, with the blocking proportion being 25% to 50%; and after sintering, the thickness of the formed blocking layer is between 5 μm and 30 μm.

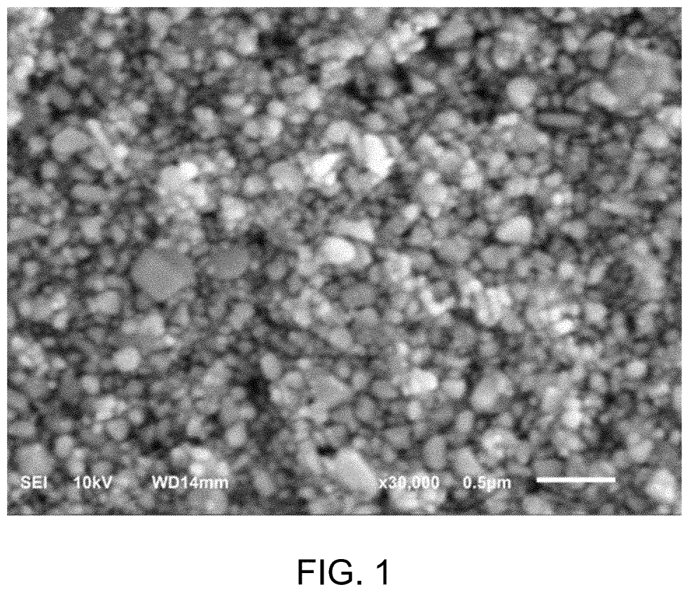

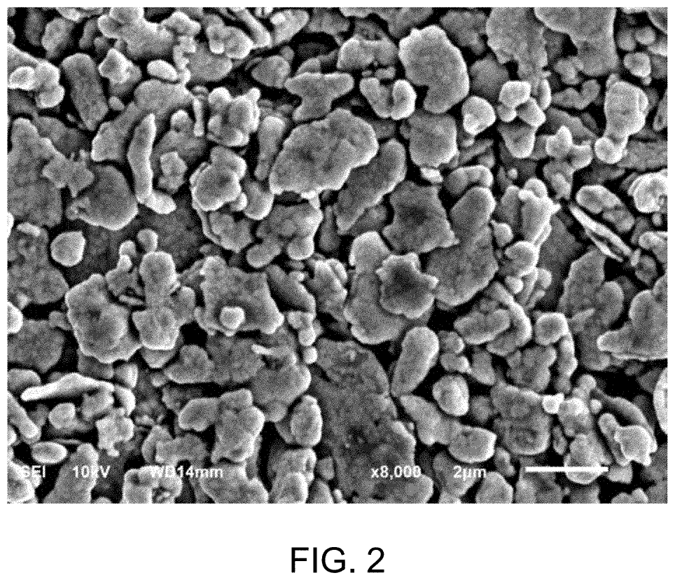

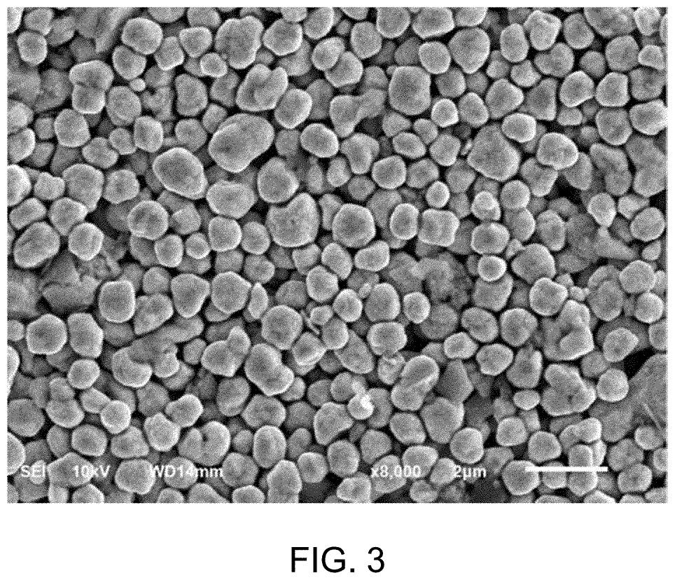

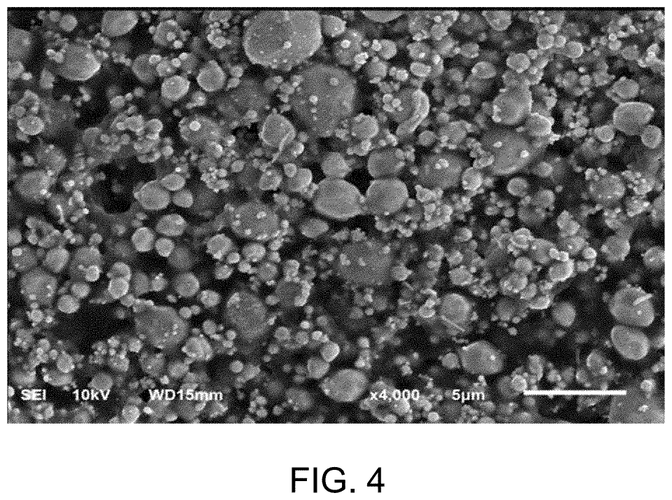

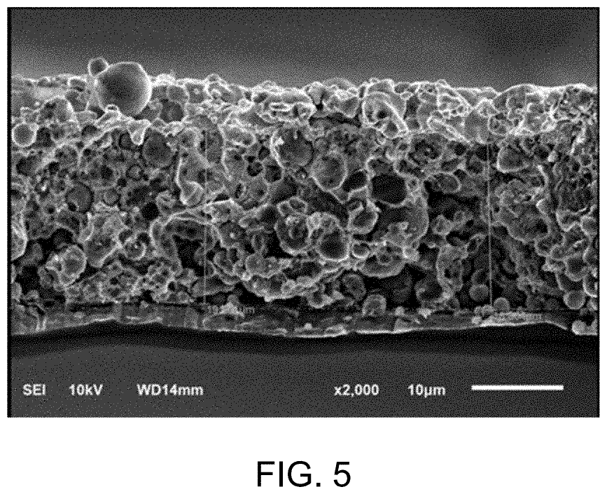

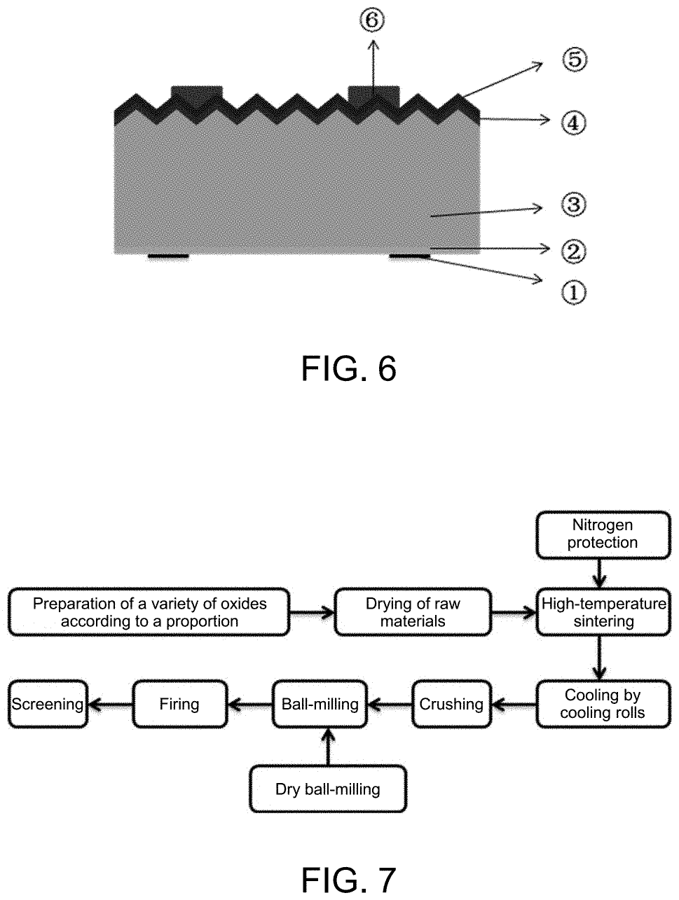

A specific experimental test was carried out by the present invention, and the test results are shown in Table 1 (Test Result of Full-Area Aluminum Back Surface Field Back-Side Silver Paste) and Table 2: (Test Result of Reliability of Full-Area Aluminum Back Surface Field Back-Side Silver Paste). Electron microscopy images are shown as FIGS. 1-5. The schematic diagram of a cell structure of the present invention is shown as FIG. 6.

TABLE 1
Test Result of Full-Area Aluminum Back
Surface Field Back-Side Silver Paste

| Sample | Uoc/v | Isc/A | Rs/mΩ | Rsh/Ω | FF/% | Eta/% |
|---|---|---|---|---|---|---|
| BSL | 0.6365 | 9.015 | 1.33 | 125.2 | 80.27 | 18.74 |
| T-SUN | 0.6381 | 9.038 | 1.47 | 79.8 | 80.08 | 18.79 |

TABLE 2
Test Result of Reliability of Full-Area Aluminum
Back Surface Field Back-Side Silver Paste

| | | | | Tensile Strength |
|---|---|---|---|---|
| | Tensile | Aging Tensile | Aging Tensile | After Poaching |
| Sample | Strength/N | Strength 0.5 h | Strength 1 h | 85° C./0.5 h |
| 1 | 3.136 | 2.668 | 3.148 | 4.075 |
| 2 | 2.333 | 1.298 | 3.303 | 2.383 |

Since the silver powders with different grain sizes and shapes are chosen to be used in cooperation in the present invention, the bulk density of a conducting film is increased, the contact area between silver particles is enlarged, the contraction force of the conducting film is decreased, and the electric conductivity of the paste is increased.

The low-melting-point metal powder in the present invention has very high sintering flow activity, and plays a role of silver-aluminum barrier agent in the whole paste system to prevent interpenetration between silver and aluminum and contact between silver and a silicon wafer. The matching of silver-aluminum barrier agents with different grain sizes can greatly decrease contact resistance, thereby increasing the efficiency of cells. However, excessive addition of the low-melting-point metal powder will lead to a decrease in the electric conductivity of the back-side silver paste. Moreover, the addition of some low-melting-point metal powder can also reduce the usage of silver powder, thereby reducing cost.

In the present invention, according to the different sensitivities of the organic resin and the organic additives to temperature, the organic resin and the organic additives are dispersed separately, which not only can save time, but also can prevent the organic additives from deteriorating under high temperature.

The advantages of the polyvinyl butyral resin in the present invention are as follows: thickening is fast, the leveling property of the paste can be improved, and unsatisfactory lapping property between the paste and aluminum paste, high series resistance and other problems caused by poor rheological property.

The full-area aluminum back surface field back-side silver paste can be directly printed on aluminum back surface field paste, ensuring that the aluminum back surface field paste has considerable welding tensile strength and aging tensile strength and preventing the severe electric leakage problem caused by metal defects as a result of the direct contact between silver and a silicon wafer, and thereby the photoelectric conversion efficiency of crystalline silicon cells can be increased. Moreover, back electrode width and printed pattern can be adjusted optionally, thereby reducing the cost of back electrode paste.

Since the full-area aluminum back surface field back-side silver paste adopts the matching of the high-melting-point glass powder and the low-melting-point glass powder for use, the usage of leaded glass powder is reduced. Moreover, the glass powders are adjusted to have appropriate activity, so that the glass powders and the silver powder have appropriate wettability, enabling the paste to have appropriate sintering temperature, and thereby the overall properties of the paste are improved.

By using the organic carrier, through the matching of the different solvents, the silver paste can have layered volatility, preventing the problem of too fast volatilization or too much ash content occurring in the process of paste sintering. Keeping layered volatility can prevent the production of pores on the surface of the electrode or the remaining of too much non-conductive material on the electrode, improving aging tensile strength and the electric property of the product.

1. A full-area aluminum back surface field back-side silver paste, comprising: 10 to 80 parts by weight of silver powder with purity higher than 99.99% under special requirements; 0.5 to 5 parts by weight of homemade lead-free main glass powder; 0 to 3 parts by weight of low-melting-point auxiliary glass powder; 1 to 50 parts by weight of low-melting-point metal powder under special requirements; 15 to 50 parts by weight of organic binder; and 0.01 to 1 part by weight of organic additives.

2. The full-area aluminum back surface field back-side silver paste of claim 1, wherein the silver powder under special requirements is a spherical silver powder, a hollow spherical silver powder, a flaky silver powder or a superfine silver powder; the grain size D50 of the spherical silver powder is 1 μm to 13 μm; the grain size D50 of the hollow spherical silver powder is 3 μm to 20 μm; the grain size D50 of the flaky silver powder is 2 μm to 30 μm; the grain size D50 of the superfine silver powder is 0.1 μm to 3 μm, and the specific surface area of the silver powder under special requirements is 1.5 m²/g to 5 m²/g.

3. The full-area aluminum back surface field back-side silver paste of claim 2, wherein the grain size D50 of the spherical silver powder is about 7 μm to 8 μm; the grain size D50 of the spherical micro-nano silver powder is about 1 μm to 3 μm; the grain size D50 of the flaky silver powder is about 5 μm to 10 μm; and the grain size D50 of the superfine spherical nano silver powder is about 50 nm to 100 nm.

4. The full-area aluminum back surface field back-side silver paste of claim 1, wherein the homemade lead-free main glass powder is prepared by melting several of Bi₂O₃, B₂O₃, SiO₂, Al₂O₃, CuO, ZnO, Na₂O, MnO₂, CaO, TiO₂, Cr₂O₃, SrO, BaO, NiO and TeO₂, with the grain size D50 being controlled at 0.5 μm to 5 μm and the softening point being controlled at 400° C. to 600° C.

5. The full-area aluminum back surface field back-side silver paste of claim 1, wherein the low-melting-point auxiliary glass powder is prepared by melting several of PbO, Bi₂O₃, MnO₂, TeO₂, B₂O₃, SiO₂, Al₂O₃, CuO, ZnO, TiO₂, Cr₂O₃, NiO and Li₂CO₃, with the grain size D50 being controlled at 1 μm to 9 μm and the softening point being controlled at 380° C. to 500° C.

6. The full-area aluminum back surface field back-side silver paste of claim 1, wherein the low-melting-point metal powder under special requirements includes one or more of powder of copper, vanadium, potassium, indium, tellurium, bismuth, tin, antimony, lead, selenium and other low-melting-point metals and their alloys, wherein the spherical metallic bismuth powder under special requirements has a melting point from 200° C. to 300° C. and a grain size from about 0.1 μm to about 8 μm; the metallic tin powder under special requirements has a melting point from 200° C. to 300° C. and a grain size from about 0.5 μm to about 10 μm; the metallic antimony powder under special requirements has a melting point from 300° C. to 400° C. and a grain size from about 0.1 μm to about 8 μm; and the metallic lead powder under special requirements has a melting point from 400° C. to 500° C. and a grain size from about 0.1 μm to about 5 μm.

7. A preparation method for the full-area aluminum back surface field back-side silver paste of claim 1, comprising the following steps:
step 1: a low-melting-point nano metal powder is uniformly dispersed separately with a dispersant for later use;
step 2: preparation of the organic binder: an organic resin and the organic additives are respectively soaked with an organic solvent; the organic resin is soaked while being heated and stirred under a temperature of about 90° C. for 1 to 3 hours, and a thixotropic agent is soaked while being heated and stirred under a temperature of about 40° C. for 1 to 2 hours; the organic resin and the thixotropic agent are then mixed with other organic additives and organic solvent according to a certain proportion, giving a transparent and homogeneous organic binder;
step 3: preparation of an inorganic binder which is glass powder and auxiliary glass powder: after being weighed according to percentages by weight, various materials are dry-mixed in a V-type mixer, and after uniform mixing, the mixture is dried in a constant-temperature drying oven under about 200° C. for 2 to 5 hours; after being taken out, the mixture is sintered and smelted in a muffle furnace under 900° C. to 1100° C. for 1 to 2 hours, and during smelting, a high-temperature nitrogen vacuum-protected sintering technique is adopted, the application of which can overcome the technical problem on how to prepare low-melting-point, valence state-table glass powder; and after being taken out of the muffle furnace, the glass is cooled by cooling rolls, ball-milled, dried and screened, giving the inorganic binder for the full-area aluminum back surface field back-side silver paste; and
step 4: after the silver powder, the organic binder, the inorganic binder, the organic additives and the pre-dispersed low-melting-point nano metal powder are dispersed and mixed according to a certain proportion, the mixture is ground using a three-roll grinder, 3 to 5 times with fine rolls and 2 to 3 times with rough rolls, so that the mixture is uniformly dispersed until fineness is less than 20 giving the prepared full-area aluminum back surface field back-side silver paste.

8. An application of the full-area aluminum back surface field back-side silver paste of claim 1, wherein the full-area aluminum back surface field back-side silver paste is directly printed on an aluminum paste to prevent the severe electric leakage problem caused by metal defects as a result of the direct contact between silver and a silicon wafer, and thereby the photoelectric conversion efficiency of crystalline silicon cells can be increased; moreover, a back electrode width and a printed pattern can be adjusted optionally, thereby reducing the cost of a back electrode paste and ensuring that the back electrode paste has considerable welding tensile strength and aging tensile strength; in order to reduce unit consumption, the printed pattern of the back-side silver paste can be hollowed out, strip hollowed out or dot hollowed out, with the blocking proportion being 25% to 50%; and after sintering, the thickness of the formed blocking layer is between 5 μm and 30 μm.
